(19) United States
(12) Patent Application Publication
(10) Pub. No.: US 2014/0361276 A1
(43) Pub. Date: Dec. 11, 2014

(54) THIN FILM TRANSISTOR AND ACTIVE MATRIX ORGANIC LIGHT EMITTING DIODE ASSEMBLY AND METHOD FOR MANUFACTURING THE SAME

(71) Applicant: EverDisplay Optronics (Shanghai) Limited, Shanghai (CN)

(72) Inventors: Chia-che HSU, Shanghai (CN); Chia-chi HUANG, Shanghai (CN); Min-ching HSU, Shanghai (CN)

(21) Appl. No.: 14/298,525

(22) Filed: Jun. 6, 2014

(30) Foreign Application Priority Data
Jun. 7, 2013 (CN) 201310226626.X

(51) Int. Cl. H01L 27/32; H01L 21/265; H01L 51/56

(52) U.S. Cl. CPC H01L 27/3248; H01L 51/56; H01L 21/265
USPC 257/40; 438/34

(57) ABSTRACT

An active matrix organic light emitting diode assembly includes a substrate and a plurality of pixels on the substrate, each of the pixels at least includes an Organic Light Emitting Diode (OLED), a first Thin Film Transistor (TFT) and a second TFT, wherein: the second TFT is configured to drive the OLED; the first TFT is configured to drive the second TFT, the first TFT includes a buffer layer on the substrate, a semiconductor layer on the buffer layer, a gate insulating layer covering the semiconductor layer and a gate electrode on the gate insulating layer, and the semiconductor layer includes a source region and a drain region of first conductivity type and a bottom doped region of second conductivity type. The leakage current in AMOLED assembly may be suppressed, thereby avoiding instability and even failure of assembly operation caused by overlarge leakage current.

### CROSS REFERENCE TO RELATED APPLICATIONS

The present application claims priority under 35 U.S.C. §119 to Chinese Patent Application No. 201310226626.X, filed on Jun. 7, 2013, the entire contents of which are incorporated herein by reference.

The present disclosure relates to an active matrix organic light emitting display, and more particularly to a Thin Film Transistor (TFT) and an Active Matrix Organic Light Emitting Diode (AMOLED) assembly including the TFT and a method for manufacturing the same.

### BACKGROUND

Active Matrix Organic Light Emitting Diode (AMOLED) as a new generation display technology has advantages such as self-illumination, wide viewing angle, high contrast ratio, low power consumption, high response speed, high resolution, full color, and thinness. Thus, AMOLED is expected to be one of future mainstream display technologies.

Low Temperature Poly-Silicon (LTPS) process is usually employed in TFT array assembly portion of the AMOLED. Qualities of the TFTs and the array assembly including the TFTs will determine final display quality of the AMOLED.

FIGS. 1A˜1C illustratively show schematic diagrams of a conventional 2T1C driving circuit used in an AMOLED. As shown in FIG. 1A, in a TFT array assembly of an AMOLED, when a scan voltage Vscan turns on a switching TFT T1, a voltage on a data line may turn on a driving transistor T2 by the switching TFT T1 so as to drive an Organic Light Emitting Diode (OLED) to emit light and meanwhile to charge a storage capacitor Cs.

As shown in FIG. 1B, when Vscan turns off and thus the switching transistor T1 is turned off, because of the presence of the storage capacitor, the driving transistor T2 maintains on so as to keep the OLED emitting light. However, as shown in FIG. 1C, if there is leakage current in the switching transistor T1, the voltage across the storage capacitor will change, thereby influencing the stability of the OLED.

FIG. 2 illustratively shows a current leakage path when a switching TFT is turned off. As shown in FIG. 2, a TFT 100 includes a substrate 130, a buffer layer on the substrate, a semiconductor layer 135 on the buffer layer, a gate insulating layer covering the semiconductor layer 135, a gate electrode 150 on the gate insulating layer, an interlayer dielectric layer covering the gate electrode, and source (S)/drain (D) electrodes 158 formed on the interlayer dielectric layer and electrically connected to a source region/a drain region 136/138 of the TFT through contact holes 156. The buffer layer may include a silicon nitride layer 132 and a silicon oxide layer 134 on the silicon nitride layer. The semiconductor layer 135 may be a LTPS layer. The semiconductor layer includes the source region/drain region 136 and 138 on both sides of the gate electrode, and a channel region 142, a Lightly Doped Drain (LDD) region and an inter-gate heavily doped region 144 which are between the source region and the drain region. The gate insulating layer may include a silicon oxide layer 146 and a silicon nitride layer 148 on the silicon oxide. The gate electrode 150 may be molybdenum. The interlayer dielectric layer may include a silicon nitride layer 152 and a silicon oxide layer 154 on the silicon nitride layer 152.

Referring to FIGS. 1A-1C and FIG. 2, taking a PMOS as an example, after the switching transistor T1 is turned off, there may be three current leakage paths. The first leakage path is: the drain electrode—the top poly-silicon/silicon oxide interface—the source electrode. The second leakage path is: the drain electrode—the P+ doped region—the side poly-silicon/silicon oxide interface—the P+ doped region—the source electrode (not shown). The third leakage path is: the drain electrode—the P+ doped region—the bottom poly-silicon/silicon oxide interface—the P+ doped region—the source electrode.

Thus, a method and a structure which may reduce the leakage current of a TFT and increase light emitting stability of an OLED is needed.

The above information disclosed in the background portion is only for purposes of enhancing understanding of the background of the present disclosure, and thus it may include information which does not constitute prior art known to one of ordinary skill in this art.

### SUMMARY OF THE INVENTION

The present application discloses a TFT and an AMOLED assembly including the TFT and a method for manufacturing the same, which may suppress the leakage current in the AMOLED assembly, and therefore avoid instability and thereby failure of the assembly operation caused by an overlarge leakage current.

Other properties and advantages of the present disclosure will become clear through the following detailed description or may be obtained partially by the practice of the present disclosure.

According to an aspect of the present disclosure, an AMOLED assembly is provide, which includes a substrate and a plurality of pixels on the substrate, each of the pixels at least includes an OLED, a first TFT and a second TFT, wherein: the second TFT is configured to drive the OLED; the first TFT is configured to drive the second TFT, the first TFT includes a buffer layer on the substrate, a semiconductor layer on the buffer layer, a gate insulating layer covering the semiconductor layer and a gate electrode on the gate insulating layer, and the semiconductor layer comprises a source region and a drain region which are of a first conductivity type; and the semiconductor layer further includes a bottom doped region of a second conductivity type which is at the bottom of the semiconductor layer and is below the source region and the drain region.

The semiconductor layer may be a LTPS thin film.

The bottom doped region may have an impurity concentration greater than 9×10¹⁴/cm².

The AMOLED assembly further includes: a data line; a gate line intersecting the data line; and a storage capacitor; wherein the first TFT is electrically connected with the gate line, the data line and a gate electrode of the second TFT, and one terminal of the storage capacitor is electrically connected with the gate electrode of the second TFT.

The buffer layer may include a silicon nitride layer and a silicon oxide layer on the silicon nitride layer.

An upper surface of the silicon oxide layer may be processed by using one of O₂, N₂, NH₃, and H₂.

The gate insulating layer may include a silicon oxide layer and a silicon nitride layer on the silicon oxide layer.

The semiconductor layer further comprises lightly doped drain regions between the gate electrode and the source region and between the gate electrode and the drain region.

The first TFT and/or the second TFT may include a plurality of gate electrodes.

The substrate may include one of a glass substrate and a flexible substrate.

The first conductivity type is one of N type and P type, and the second conductivity type is the other one of N type and P type.

According to another aspect of the present disclosure, a TFT serving as a switching element in an active matrix organic light emitting display is provided, which includes: a substrate; a silicon oxide layer on the substrate; a semiconductor layer on the silicon oxide layer, including a source region and a drain region which are of a first conductivity type; a gate insulating layer covering the semiconductor layer; and a gate electrode on the gate insulating layer; wherein the semiconductor layer further includes a bottom doped region of a second conductivity type which is at the bottom of the semiconductor layer and is below the source region and the drain region.

The bottom doped region may have an impurity concentration greater than 9×10¹⁴/cm².

The semiconductor layer may be a LTPS thin film.

According to a further aspect of the present disclosure, a method for manufacturing an AMOLED assembly is provided, which includes: preparing a substrate having a buffer layer thereon; forming a first semiconductor layer and a second semiconductor layer on the buffer layer, the first semiconductor layer being used for a first TFT, and the second semiconductor layer being used for a second TFT; forming a gate insulating layer, a first gate electrode and a second gate electrode on the first semiconductor layer and the second semiconductor layer; injecting an impurity of a second conductivity type into a bottom of the first semiconductor layer by ion implantation to form a bottom doped region of the second conductivity type which is below predetermined regions of the first TFT in which a source region and a drain region are to be formed; and injecting an impurity of a first conductivity type into the first semiconductor layer to form the source region and the drain region of the first TFT.

The impurity of the first conductivity type is one of an N type impurity and a P type impurity, and the impurity of the second conductivity type is the other one of the N type impurity and the P type impurity.

The bottom doped region may have an impurity concentration greater than 9×10¹⁴/cm².

The buffer layer may include a silicon nitride layer and a silicon oxide layer on the silicon nitride layer.

Forming the first semiconductor layer and the second semiconductor layer on the buffer layer may include: forming an amorphous silicon film on the buffer layer; and crystallizing the amorphous silicon film into a poly-silicon film, and patterning the poly-silicon film to form the first semiconductor layer and the second semiconductor layer.

After forming the first semiconductor layer and the second semiconductor layer, the method may further include: performing channel doping on the first semiconductor layer and the second semiconductor layer.

Before forming the gate insulating layer and the first gate electrode and the second gate electrode, the method may further include: forming a source region and a drain region of the second TFT in the second semiconductor layer by ion implantation.

Forming the gate insulating layer and the first gate electrode and the second gate electrode may include: forming a silicon oxide layer on the first semiconductor layer and the second semiconductor layer; forming a silicon nitride layer on the silicon oxide layer; forming a gate metal layer on the silicon nitride layer; forming a photoresist pattern on the gate metal layer; and etching the gate metal layer and the silicon nitride layer using the photoresist pattern as a mask to form the gate electrodes and silicon nitride feet below the gate electrodes, wherein the silicon nitride feet have a width wider than that of the gate electrodes.

Forming the bottom doped region may include injecting the impurity of the second conductivity type by ion implantation using the gate electrodes and the silicon nitride feet as a mask.

Forming the source region and the drain region of the first TFT includes injecting the impurity of the first conductivity type by ion implantation using the gate electrodes and the silicon nitride feet as a mask.

A LDD region may be formed in the first semiconductor layer at the same time when the source region and the drain region of the first TFT are formed.

A source region and a drain region of the second TFT and a LDD region are formed in the second semiconductor layer at the same time when the source region and the drain region of the first TFT are formed.

After forming the source region and the drain region of the first thin film transistor, the method further includes: forming an interlayer dielectric layer on a resulted structure; forming an etching masking pattern on the interlayer dielectric layer; forming a contact hole exposing the source region and the drain region of the first TFT by etching; depositing a data line layer on a resulted structure and filling the contact hole; forming a data wiring comprising a source electrode/drain electrode by patterning, the source electrode/drain electrode being electrically connected with the source region/drain region of the first TFT through the contact hole; and forming a passivation layer covering the data wiring.

The above method may further includes: after forming the buffer layer, processing an upper surface of the buffer layer by using O₂, N₂, NH₃, or H₂.

According to the technical solutions of the present disclosure, the leakage current in a switching TFT of an AMOLED array substrate may be suppressed, thereby avoiding instability and thereby failure of the assembly operation (this may thereby influence the image quality of the display) caused by an overlarge leakage current. The technical solutions in of the present disclosure may be applied in a new generation display such as LTPS Liquid Crystal Display (LTPS-LCD).

### BRIEF DESCRIPTION OF THE DRAWINGS

By the description of exemplary embodiments with reference to drawings, the above and other features and advantages of the present disclosure may become more obvious.

FIGS. 1A, 1B and 1C illustratively show schematic diagrams of a conventional 2T1C driving circuit used in an AMOLED;

FIG. 2 illustratively shows a current leakage path when a switching TFT is turned off;

FIG. 3 illustratively shows a schematic circuit diagram of an AMOLED array substrate;

FIG. 4 illustratively shows a schematic diagram of a P type Metal Oxide Semiconductor Field Effect Thin Film Transistor (PMOS TFT) according to an exemplary embodiment, which may serve as a switching transistor in the AMOLED array substrate as shown in FIG. 3;

FIG. 5 illustratively shows an operation schematic diagram when a transistor according to the present disclosure is turned off in a case where the transistor is used as a switching transistor in an AMOLED array substrate;

FIG. 6 illustratively shows an operating principle of a switching transistor according to an exemplary embodiment of the present disclosure;

FIG. 7 illustratively shows a schematic diagram of an N type Metal Oxide Semiconductor Field Effect Thin Film Transistor (NMOS TFT) according to an exemplary embodiment, which may serve as a switching transistor in an AMOLED array substrate; and

FIGS. 8A, 8B, 8C, 8D, 8E, 8F, 8G, 8H and 8J illustratively shows a method for manufacturing the AMOLED array substrate according to an exemplary embodiment of the present disclosure.

### DETAILED DESCRIPTION OF THE EMBODIMENTS

Now, exemplary embodiments will be described more fully with reference to drawings. However, the exemplary embodiments may be implemented in various manners, and shall not be interpreted as limited to the embodiments set forth herein; instead, providing these embodiments will make the present disclosure more comprehensive and complete and will fully convey the conception of the exemplary embodiments to one of ordinary skill in this art. In the drawings, thicknesses of regions and layers are exaggerated for clarity purposes. Through the drawings similar reference signs indicate the same or similar structures and their detailed description will be omitted.

In addition, the features, structures or characteristics described herein may be combined in one or more embodiments in any suitable manner. In the following description, many specific details are provided to give sufficient understanding of the embodiments of the present disclosure. However, one of ordinary skill in this art will appreciate that the technical solutions in the present disclosure may be practiced without one or more of the specific details, or other methods, elements and materials and so on may be employed. In other conditions, well-known structures, materials or operations are not shown or described in detail to avoid confusion of respective aspects of the present disclosure.

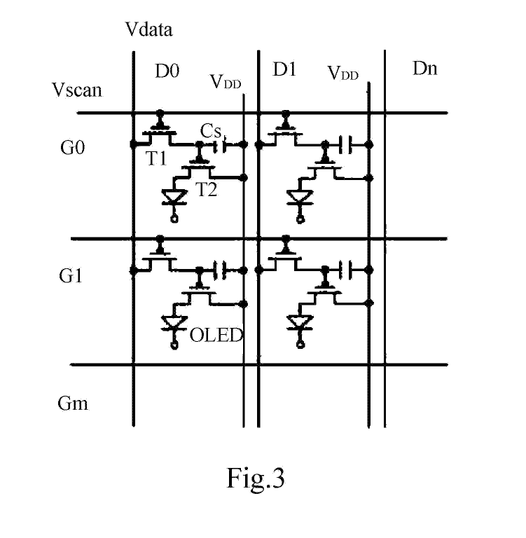

FIG. 3 illustratively shows a schematic circuit diagram of an AMOLED array substrate.

As shown in FIG. 3, the AMOLED array substrate according an exemplary embodiment includes a plurality of pixels, each of which at least includes an OLED, a switching TFT T1 and a driving TFT T2. The switching TFT T1 is configured to drive the driving TFT T2. The driving TFT T2 is configured to drive the OLED.

According to an exemplary embodiment, the AMOLED assembly further includes data lines D0˜Dn, gate lines G0˜Gm intersecting the data lines and storage capacitors Cs. The switching TFT T1 is electrically connected with a gate line, a data line and a gate electrode of the driving TFT T2. One terminal of a storage capacitor Cs is electrically connected with the gate electrode of the driving TFT T2, and the other terminal of the storage capacitor Cs is electrically connected with a power supply V_{DD}.

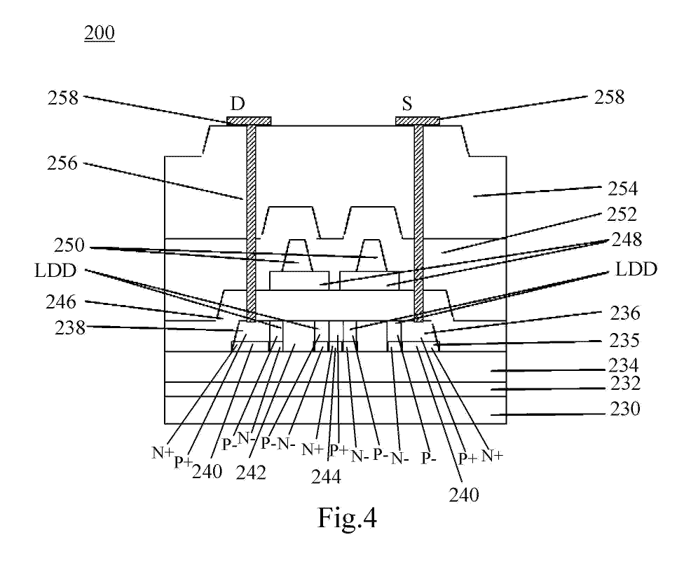

FIG. 4 illustratively shows a schematic diagram of a PMOS TFT according to an exemplary embodiment. The P type transistor may serve as the switching transistor T1 in the AMOLED array substrate as shown in FIG. 3. However, the present disclosure is not limited to this. The transistor according to the present disclosure may be employed in AMOLED assembly with various types of driving circuits.

A two-gate structure is shown in FIG. 4. However, the present disclosure is not limited to this. It is easily appreciated that the present disclosure may also be applied in a single gate structure or other structures.

As shown in FIG. 4, a PMOS TFT 200 according an exemplary embodiment includes a substrate 230, a buffer layer on the substrate, a semiconductor layer 235 on the buffer layer, a gate insulating layer covering the semiconductor layer, and a gate electrode 250, an interlayer dielectric layer covering the gate electrode, and a source electrode/drain electrode 258 formed on the interlayer dielectric layer and electrically connected with the source region/drain region of the TFT through contact holes 256, wherein the gate electrode 250, the interlayer dielectric layer and the source electrode/drain electrode 258 are on the gate insulating layer.

The substrate 230 may be a glass substrate, a flexible substrate or other substrates.

The buffer layer may include a silicon nitride layer 232 and a silicon oxide layer 234 on the silicon nitride layer. However, the present disclosure is not limited to this.

The semiconductor layer 235 may be a LTPS layer. However, the present disclosure is not limited to this. The semiconductor layer 235 includes a P type source region/drain region 236 and 238 on both sides of the gate electrode, a channel region 242, a LDD region and an inter-gate heavily doped region 244 which are between the source region and the drain region. However, the present disclosure is not limited to this.

According to an exemplary embodiment, the semiconductor layer 235 further includes a N+ bottom doped region 240 which is at the bottom of the semiconductor layer and is below the source region/drain region 236 and 238. For example, the doped region 240 may be doped with P, As and so on. An impurity concentration of the doped region 240 may be greater than 9×10¹⁴/cm², for example.

The gate insulating layer may include a silicon oxide layer 246 and a silicon nitride layer 248 on the silicon oxide layer, for example. However, the present disclosure is not limited to this.

For example, the gate electrode 250 may be metal such as molybdenum, aluminum, an alloy of aluminum and nickel, an alloy of molybdenum and tungsten, chromium, or copper. A combination of thin films of the above materials may be used.

The interlayer dielectric layer may include a silicon nitride layer 252 and a silicon oxide layer 254 on the silicon nitride layer 252, for example. However, the present disclosure is not limited to this.

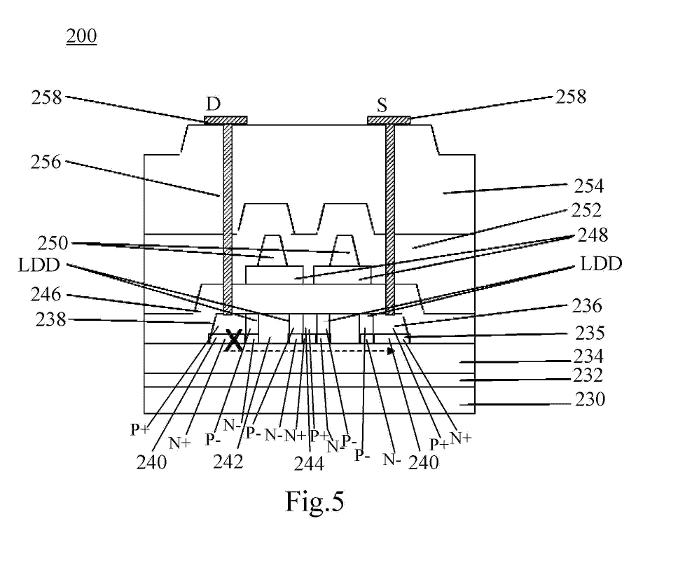

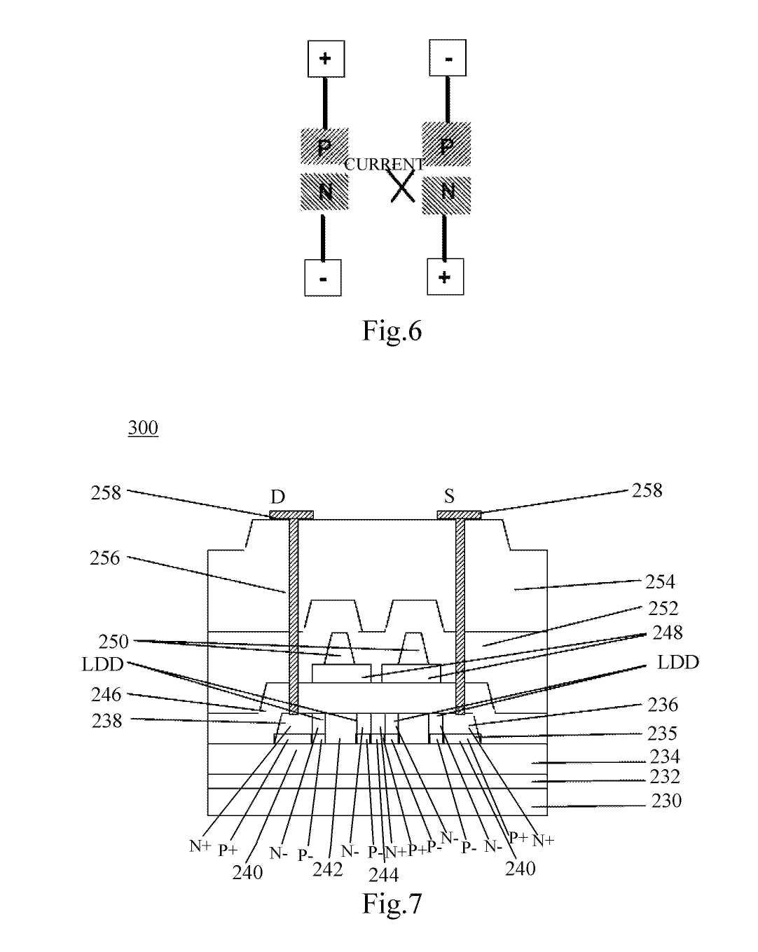

The PMOS TFT 200 according to an exemplary embodiment has a N+ bottom doped region 240 which is at the bottom of the semiconductor layer 235 and is below the source region and the drain region 236 and 238. When serving as the switching transistor in the AMOLED assembly, the leakage current when the transistor is under an off state may be effectively reduced. The operating principle of the transistor 200 according to the present disclosure will be described below with reference to FIGS. 5 and 6.

FIG. 5 illustratively shows an operation schematic diagram of a transistor according to the present disclosure when the transistor is used as a switching transistor in an AMOLED array substrate.

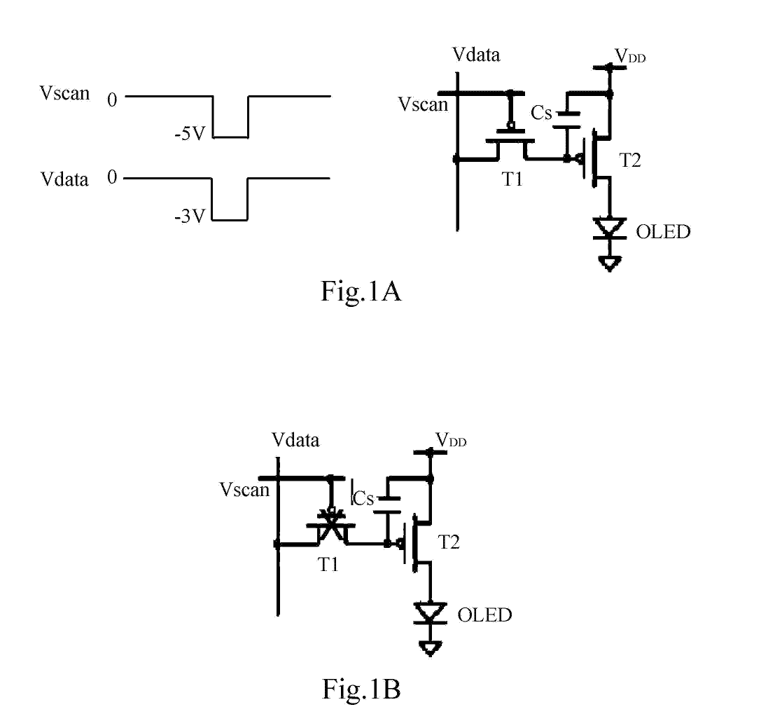

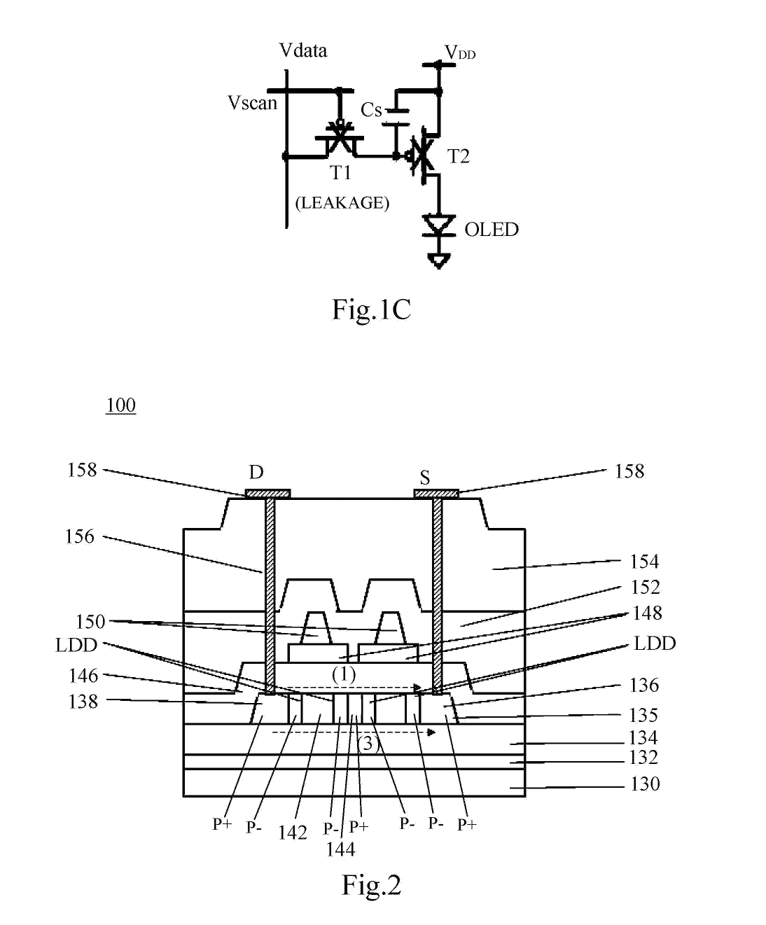

Referring to FIGS. 1A-1C and FIGS. 2 and 5, when the switching transistor T1 is turned off, the driving transistor T2 maintains on because of the presence of the storage capacitor.

Referring to FIG. 2, when there is no N+ doped region at the bottom of the semiconductor layer, there exists a current leakage path: the drain electrode—the P+ doped region—the bottom poly-silicon/silicon oxide interface—the P+ doped region—the source electrode.

Referring to FIG. 6, when there exists the N+ bottom doped region 240 which is at the bottom of the semiconductor layer and is below the source region and the drain region 236 and 238 according to an exemplary embodiment of the present disclosure, a depletion region is formed at the P-N interface. Because of the high resistance property of the depletion region, current flowing is blocked. Thus, the above third current leakage path may be effectively blocked after the switching transistor T1 is turned off, thereby reducing the leakage current.

Although the present disclosure is described above taking the PMOS TFT as an example, one of ordinary skill in this art will easily appreciate that the operating principle of the present disclosure may also be applied in a NMOS TFT.

FIG. 7 illustratively shows a schematic diagram of an NMOS TFT according to an exemplary embodiment. The N type transistor 300 may serve as the switching transistor in the AMOLED array substrate.

Referring to FIG. 7, the NMOS TFT according to an exemplary embodiment has a P+ bottom doped region which is at the bottom of the semiconductor layer and is below the source region and the drain region. When serving as the switching transistor in the AMOLED array substrate, the leakage current when the transistor is under an off state may be effectively reduced. Since the operating principle of the NMOS TFT is similar to the PMOS TFT, its detailed description will be omitted.

A method for manufacturing the AMOLED array substrate according to an exemplary embodiment of the present disclosure will be described below. The AMOLED array substrate includes a PMOS TFT having an N+ bottom coped region as the switching transistor.

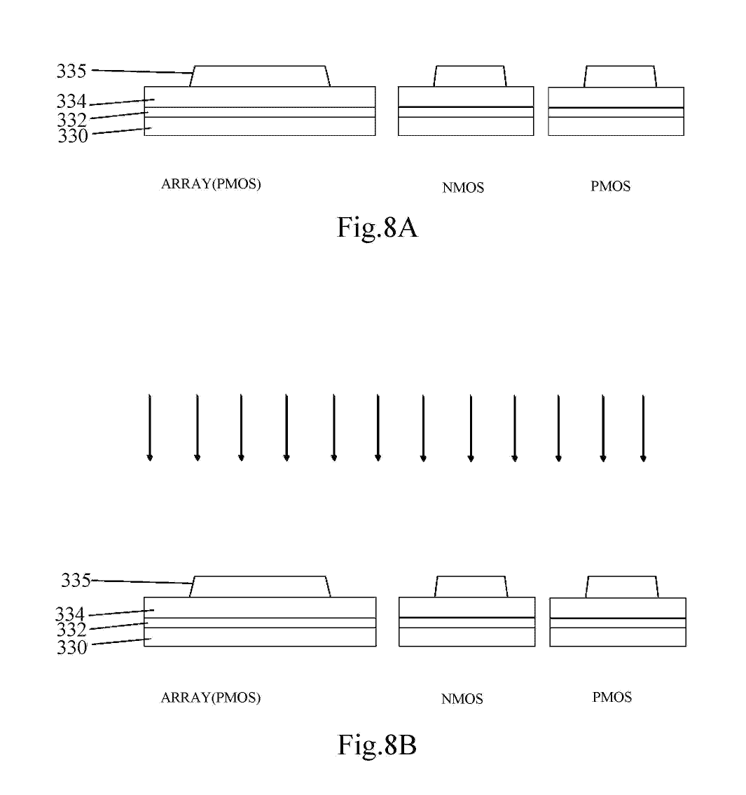

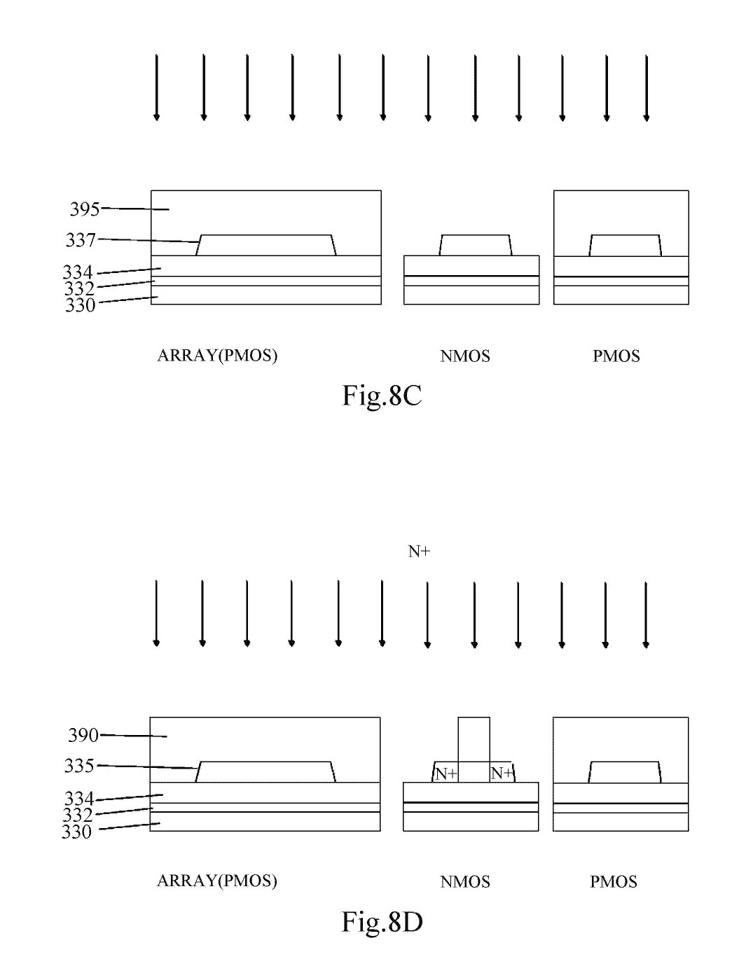

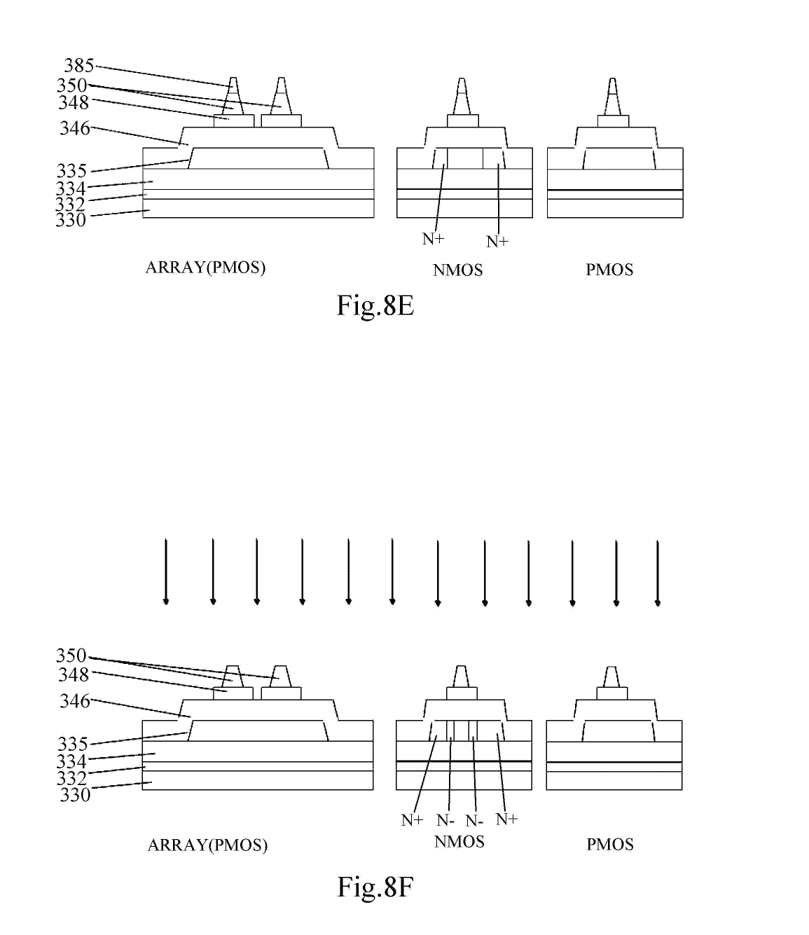

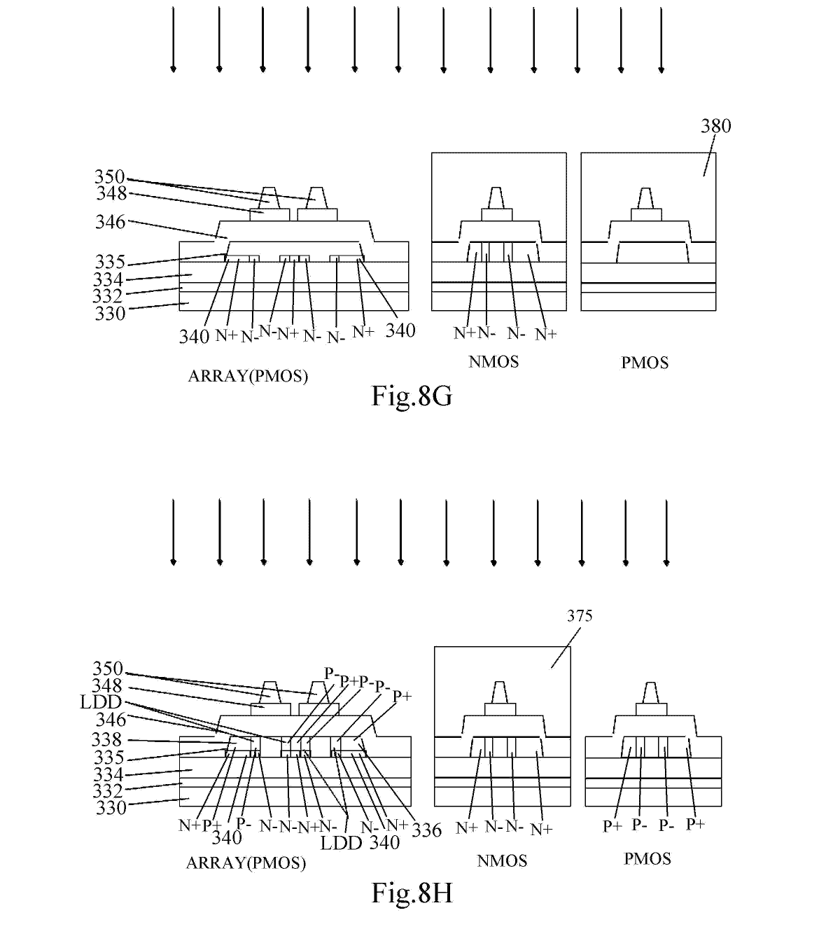

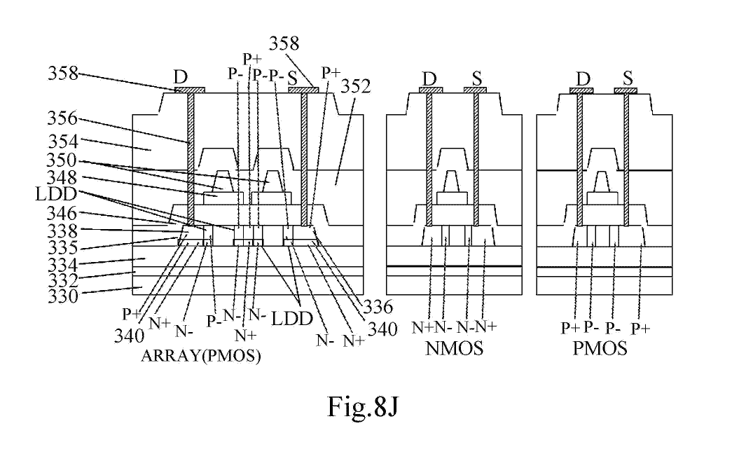

FIGS. 8A-8J illustratively show a method for manufacturing the AMOLED array substrate according to an exemplary embodiment of the present disclosure. By the shown manufacturing method, a PMOS TFT having a bottom N+ doped region and applied in the AMOLED array substrate according to an exemplary embodiment of the present disclosure may be manufactured on a substrate. In addition, an NMOS TFT and/or a PMOS TFT having no bottom doped regions may be manufactured simultaneously as required.

Referring to FIG. 8A, in the manufacturing method of the AMOLED assembly according to an exemplary embodiment of the present disclosure, a substrate 330 including a buffer layer thereon is first prepared. The substrate 330 may be a glass substrate or a flexible substrate, or may be other suitable substrates. The buffer layer may include a silicon nitride layer 332 and a silicon oxide layer 334 on the silicon nitride layer. However, the present disclosure is not limited to this.

Optionally, an upper surface of the silicon oxide layer may be processed by using O₂, N₂, NH₃, or H₂ to suppress the interface leakage current by reducing amount of defects such as dangling bond.

Then, a semiconductor layer 335 is formed on the substrate. The semiconductor layer may be a LTPS layer. For example, an amorphous silicon (a-Si) thin film may be formed by methods such as plasma enhanced chemical vapor deposition (PECVD) method, and then the amorphous silicon is crystallized by methods such as Excimer Laser Annealing (ELA), and a poly-silicon (Poly-Si) film may be obtained.

Then, a photoresist is formed on the substrate, and a photoresist pattern is obtained by patterning using photolithograph. Using the photoresist pattern as a mask, the poly-silicon film is patterned to form a plurality of semiconductor layer patterns 335. Then, the photoresist pattern is peeled off

Next, referring to FIG. 8B, doping for adjusting a threshold voltage Vth may be performed on the semiconductor layer using BF₃, for example.

Next, as shown in FIG. 8C, a photoresist is formed in the resulted structure and patterning is performed to form a photoresist pattern 395, exposing a region in which the NMOS TFT is to be formed. Then, implantation is performed on the semiconductor layer of the NMOS TFT using a P type dopant such as BF₃ so as to complete channel doping of the NMOS.

Next, as shown in FIG. 8D, after removing the photoresist pattern 395, a photoresist pattern 390 is formed in the resulted structure, exposing predetermined regions of the NMOS TFT in which a source region and a drain region are to be formed.

The predetermined regions of the semiconductor layer of the NMOS TFT in which a source region and a drain region are to be formed are doped using N type impurities such as P, As and so on so as to form the source region and the drain region. Then, the photoresist pattern 390 is peeled off.

Next, as shown in FIG. 8E, a gate insulating layer covering the semiconductor layer is formed using methods such as Chemical Vapor Deposition (CVD). The gate insulating layer may include a silicon oxide material layer and a silicon nitride material layer on the silicon oxide material layer, for example. Next, a gate metal layer is deposited on the gate insulating layer. Metal such as molybdenum, aluminum, an alloy of aluminum and nickel, an alloy of molybdenum and tungsten, chromium, or copper is usually used in the gate metal layer. A combination of thin films of the above materials may be used. A photoresist layer is formed on the gate metal layer and patterning is performed to form a photoresist pattern 385. Using the photoresist pattern 385 as a mask, a portion of the gate metal layer and the gate insulating layer is etched to obtain a gate line (not shown), a gate electrode and a silicon nitride foot below the gate electrode. The silicon nitride foot has a width wider than that of the gate electrode.

Next, optionally, referring to FIG. 8F, N type doping is performed on the semiconductor layer of the NMOS using dopant such as P, As and so on to obtain a LDD region of the NMOS TFT.

Referring to FIG. 8G, a photoresist is formed in a resulted structure and pattering is performed to form a photoresist pattern 380, exposing a region of the PMOS TFT where the bottom N+ doped region is to be formed. N type impurities such as P, As and so on is injected into the bottom of the semiconductor layer of the PMOS TFT by ion implantation so as to form the N+ bottom doped region 340 below the source region and drain region of the PMOS TFT. In addition, The N+ bottom doped region may also be formed below the P type heavily doped region between gate electrodes. Then, the photoresist pattern is removed.

Next, as shown in FIG. 8H, a photoresist is formed in a resulted structured and patterning is performed to form a photoresist pattern 375 covering the NMOS TFT. Using the gate structure including the gate electrode and the silicon nitride foot as a mask, P type dopant such as BF₃ is injected into the semiconductor layer of the PMOS TFT by ion implantation so as to form the source region and the drain region 336 and 338 of the PMOS TFT.

According to the embodiment, before the P+ doping is performed by ion implantation, N+ doping is performed on the Poly-Si bottom layer by ion implantation. Then, P+ doping is performed in the Poly-Si by ion implantation to form the source region and the drain region. As such, a P-N junction structure formed between two layers, i.e., an upper layer and a lower layer, may reduce the whole leakage current of the assembly.

Because of the silicon nitride foot structure, a P type LDD region may be formed in a self-alignment manner in this process. This may avoid occurrence of short channel effect and hot carrier effect when size of a high resolution display assembly is relatively small. Furthermore, a phenomenon of the assembly failure and corruption and a large leakage current will not occur when the assembly is operating under a relatively higher voltage. Then, the photoresist pattern is peeled off.

Next, as shown in FIG. 8J, subsequent processes are performed on the resulted structure.

The subsequent processes are similar to conventional processes, and their detailed descriptions are omitted. For example, interlayer dielectric layers 352 and 354 are formed on a resulted structure. An etching masking pattern is formed on the interlayer dielectric layers. A contact hole 356 exposing the source region and the drain region 336 and 338 of the switching TFT is formed by etching. A data line layer is deposited on a resulted structure and the contact hole is filled. A data wiring including a source electrode/a drain electrode 358 is formed by patterning. The source electrode/drain electrode 358 is electrically connected with the source region/drain region of the switching transistor by the contact hole 356. Then, a process for forming a passivation layer covering the data wiring and other subsequent processes may be performed.

Detailed descriptions are made with respect to exemplary embodiments of the present disclosure. According to the exemplary embodiments of the present disclosure, by forming a P-N junction structure between an upper layer and a lower layer of the LTPS, a depletion region is formed at the P-N interface under the operation voltages of the assembly. The current flowing is blocked by the high resistance property of the depletion region. The design of the present disclosure may further reduce the whole leakage current of the assembly.

According to an exemplary embodiment, when the array substrate employs the PMOS TFT as the switching element, the formed P-N junction structure is the P+ region on the upper layer and the N+ region on the lower layer. It will be easily appreciated that when the array substrate employs a NMOS TFT as the switching element, correspondingly, the formed P-N junction structure may be the N+ region on the upper layer and the P+ region on the lower layer. As such, a required depletion region structure may be obtained under corresponding operation voltages.

According the technical solutions of the present disclosure, the leakage current of the switching TFT in the AMOLED array substrate may further be suppressed, thereby avoiding instability and even failure of the assembly operation (this may thereby influence the image quality of the display) caused by an overlarge leakage current. It shall be easily appreciated that the technical solutions according to the present disclosure may also be applied in the new generation display such as LTPS-LCD.

In addition, according to the manufacturing method of the present disclosure, manufacturing of the NMOS TFT, the PMOS TFT and the PMOS TFT or the NMOS TFT having bottom doped regions may be completed in the same process. Furthermore, a LDD region may be formed in a self-alignment manner. Thus, the manufacturing process may be simplified, and the manufacturing cost may be reduced.

The exemplary embodiments of the present disclosure are shown and described above in detail. It shall be appreciated that the present disclosure is not limited to the disclosed embodiments, and instead, the present disclosure intends to encompass various modifications and equivalent arrangements within the spirit and scope of the appending claims.

What is claimed is:

1. An active matrix organic light emitting diode assembly, comprising a substrate and a plurality of pixels on the substrate, each of the pixels at least having an organic light emitting diode, a first thin film transistor and a second thin film transistor, wherein the improvements comprise:
the second thin film transistor is to drive the organic light emitting diode;
the first thin film transistor is to drive the second thin film transistor, the first thin film transistor comprises a buffer layer on the substrate, a semiconductor layer on the buffer layer, a gate insulating layer covering the semiconductor layer and a gate electrode on the gate insulating layer, and the semiconductor layer comprises a source region and a drain region which are of a first conductivity type; and
the semiconductor layer further comprises a bottom doped region of a second conductivity type which is at the bottom of the semiconductor layer and is below the source region and the drain region, the first conductivity type being different from the second conductivity type.

2. The assembly according to claim 1, wherein the semiconductor layer is a low temperature poly-silicon thin film;
the bottom doped region has an impurity concentration greater than 9×10¹⁴/cm²;
the gate insulating layer comprises a silicon oxide layer and a silicon nitride layer on the silicon oxide layer;
the substrate comprises a glass substrate or a flexible substrate; and
the first conductivity type is one of N type and P type, and the second conductivity type is one of N type and P type.

3. The assembly according to claim 1 further comprising:
a data line;
a gate line intersecting the data line; and
a storage capacitor;
wherein the first thin film transistor is electrically connected with the gate line, the data line and a gate electrode of the second thin film transistor, and one terminal of the storage capacitor is electrically connected with the gate electrode of the second thin film transistor.

4. The assembly according to claim 1, wherein the buffer layer comprises a silicon nitride layer and a silicon oxide layer on the silicon nitride layer.

5. The assembly according to claim 4, wherein an upper surface of the silicon oxide layer is processed by using O₂, N₂, NH₃, or H₂.

6. The assembly according to claim 1, wherein the semiconductor layer further comprises lightly doped drain regions between the gate electrode and the source region and between the gate electrode and the drain region.

7. The assembly according to claim 1, wherein the first thin film transistor and/or the second thin film transistor comprise a plurality of gate electrodes.

8. A thin film transistor, which serves as a switching element in an active matrix organic light emitting display, comprising:
a substrate;
a silicon oxide layer on the substrate;
a semiconductor layer on the silicon oxide layer, comprising a source region and a drain region, which are of a first conductivity type;
a gate insulating layer covering the semiconductor layer; and
a gate electrode on the gate insulating layer;
wherein the semiconductor layer further comprises a bottom doped region of a second conductivity type which is at the bottom of the semiconductor layer and is below the source region and the drain region, the first conductivity type being different from the second conductivity type.

9. The thin film transistor according to claim 8, wherein the bottom doped region has an impurity concentration greater than 9×10¹⁴/cm².

10. The thin film transistor according to claim 8, wherein the semiconductor layer is a low temperature poly-silicon thin film.

11. A method for manufacturing an active matrix organic light emitting diode assembly, comprising:
providing a substrate having a buffer layer thereon;
respectively forming a first semiconductor layer and a second semiconductor layer on the buffer layer, the first semiconductor layer being formed as a first thin film transistor, and the second semiconductor layer being formed as a second thin film transistor;
forming a gate insulating layer, a first gate electrode and a second gate electrode on the first semiconductor layer and the second semiconductor layer;
injecting an impurity of a second conductivity type into a bottom of the first semiconductor layer by ion implantation to form a bottom doped region of the second conductivity type which is below predetermined regions of the first thin film transistor where a source region and a drain region are to be formed; and
injecting an impurity of a first conductivity type into the first semiconductor layer by ion implantation to form the source region and the drain region of the first thin film transistor.

12. The method according to claim 11, wherein the impurity of the first conductivity type is one of an N type impurity and a P type impurity, and the impurity of the second conductivity type is the other one of the N type impurity and the P type impurity;
the bottom doped region has an impurity concentration greater than 9×10¹⁴/cm²;
the buffer layer comprises a silicon nitride layer and a silicon oxide layer on the silicon nitride layer;
after forming the first semiconductor layer and the second semiconductor layer, the method further comprises: performing channel doping on the first semiconductor layer and the second semiconductor layer; and
before forming the gate insulating layer and the first gate electrode and the second gate electrode, the method further comprises: forming a source region and a drain region of the second thin film transistor in the second semiconductor layer by ion implantation.

13. The method according to claim 11, wherein the step of forming the first semiconductor layer and the second semiconductor layer on the buffer layer comprises:
forming an amorphous silicon film on the buffer layer; and
crystallizing the amorphous silicon film into a poly-silicon film, and patterning the poly-silicon film to form the first semiconductor layer and the second semiconductor layer.

14. The method according to claim 11, wherein forming the gate insulating layer and the first gate electrode and the second gate electrode comprises:
forming a silicon oxide layer on the first semiconductor layer and the second semiconductor layer;
forming a silicon nitride layer on the silicon oxide layer;
forming a gate metal layer on the silicon nitride layer;
forming a photoresist pattern on the gate metal layer; and
etching the gate metal layer and the silicon nitride layer using the photoresist pattern as a mask to form the gate electrodes and silicon nitride feet below the gate electrodes, wherein the silicon nitride feet have a width wider than that of the gate electrodes.

15. The method according to claim 14, wherein forming the bottom doped region comprises injecting the impurity of the second conductivity type by ion implantation using the gate electrodes and the silicon nitride feet as a mask.

16. The method according to claim 14, wherein forming the source region and the drain region of the first thin film transistor comprises injecting the impurity of the first conductivity type by ion implantation using the gate electrodes and the silicon nitride feet as a mask.

17. The method according to claim 16, wherein a lightly doped drain region is formed in the first semiconductor layer at the same time when the source region and the drain region of the first thin film transistor are formed.

18. The method according to claim 16, wherein a source region and a drain region of the second thin film transistor and a lightly doped drain region are formed in the second semiconductor layer at the same time when the source region and the drain region of the first thin film transistor are formed.

19. The method according to claim 11, after forming the source region and the drain region of the first thin film transistor, further comprising:
forming an interlayer dielectric layer on a resulted structure;
forming an etching masking pattern on the interlayer dielectric layer;
forming a contact hole exposing the source region and the drain region of the first thin film transistor by etching;
depositing a data line layer on a resulted structure and filling the contact hole;
forming a data wiring comprising a source electrode/drain electrode by patterning, the source electrode/drain electrode being electrically connected with the source region/drain region of the first thin film transistor through the contact hole; and
forming a passivation layer covering the data wiring.

20. The method according to claim 11, further comprising: after forming the buffer layer, processing an upper surface of the buffer layer by using O₂, N₂, NH₃, or H₂.
